(19) United States
(12) Patent Application Publication
(10) Pub. No.: US 2020/0185133 A1
(43) Pub. Date: Jun. 11, 2020

(54) ELECTRICAL TRANSIENT MATERIAL AND METHOD FOR MAKING SAME

(71) Applicant: Dongguan Littelfuse Electronics Company Limited, Dongguan City (CN)

(72) Inventors: Hao Cheng, Dongguan City (CN); Jianhua Chen, Dongguan City (CN)

(73) Assignee: Dongguan Littelfuse Electronics Company Limited, Dongguan City (CN)

(21) Appl. No.: 16/608,938

(22) PCT Filed: May 8, 2017
(86) PCT No.: PCT/CN2017/083453

§ 371 Date: Oct. 28, 2019

(51) Int. Cl. H01C 7/108; H05K 1/02

(52) U.S. Cl. CPC H01C 7/108; H05K 2201/0738; H05K 1/0257

(57) ABSTRACT

Electrical transient materials are disclosed. Furthermore, methods to provide electrical transient materials are disclosed. In one implementation, an apparatus includes an electrical transient material; and conductive particles disposed in the electrical transient material, at least one or more of the conductive particles have an irregular shape.

### BACKGROUND

### Field

The present invention relates generally to electrical transient material and methods for making electrical transient material. More particularly, the present invention relates voltage variable material (VVM) and methods for making VVM.

### Description of Related Art

Electrical transients produce high electric fields and usually high peak power that can render circuits or the highly sensitive electrical components in the circuits, temporarily or permanently non-functional. Electrical transients can include transient voltages capable of interrupting circuit operation or destroying the circuit outright. Electrical transients may arise, for example, from an electromagnetic pulse, an electrostatic discharge, lightning, a build-up of static electricity or be induced by the operation of other electronic or electrical components. An electrical transient can rise to its maximum amplitude in sub-nanosecond to microsecond times and have repeating amplitude peaks.

Materials exist for the protection against electrical transients, which are designed to respond very rapidly, ideally before the transient wave reaches its peak, to reduce the transmitted voltage to a much lower value for the duration of the electrical transients. Electrical transient materials are characterized by high electrical resistance values at low or normal operating voltages. In response to an electrical transient, the materials switch very rapidly to a low electrical resistance state. When the electrical transient dissipates, these materials return to their high resistance state. Electrical transient materials also recover very rapidly to their original high resistance value upon dissipation of the electrical transient.

Electrical transient material or VVM may be used in conventional circuit protection devices. Conventionally, electrical transient materials and VVM's exhibit a trigger voltage (V_{T}) and a clamping voltage (V_{C}). Specifically, electrical transient materials and VVM's trigger or change from a high impedance state to a low impedance state at the V_{T}, which is less than a maximum surge voltage. At some time duration after the V_{T}, the electrical transient materials or VVM's reach a steady V_{C}. Eventually, the voltage due to an electrostatic discharge event will taper from the V_{C} to zero.

In general, it is desirable for electrical transient materials and VVM's to possess low V_{T} and V_{C} values. For example, as the demand for smaller devices and integrated circuits that operate at low voltage and power levels increases, the necessity to provide electrical transient materials and VVM's that trigger and clamp at low voltage levels elevates. However, materials used in electrical transient materials and VVM's have limited further reduction of the V_{T} and V_{C} values.

Given the above-described properties and advantages of electrical transient materials and VVM's, a need exists to continue to develop improved electrical transient materials and VVM's.

### SUMMARY

Electrical transient materials and voltage variable material (VVM's) are described. Methods for providing such electrical transient materials and VVM's are also disclosed.

In some implementations, an apparatus includes an electrical transient material; and conductive particles disposed in the electrical transient material, at least one or more of the conductive particles have an irregular shape.

In further implementations, a method, includes providing an electrical transient material; and disposing conductive particles in the electrical transient material, at least one or more of the conductive particles have an irregular shape.

In yet further implementations, an apparatus includes an electrical transient material; and conductive particles disposed in the electrical transient material, at least one or more of the conductive particles have an irregular shape, wherein a width of the electrical transient material is between 0.6-1 mil or 15.2-24.4 μm, and the electrical transient material has a voltage peak voltage density of 8.2-4.9, defined as voltage peak/width in μm, and wherein the voltage peak is 125-130 V and the width is 15.2-24.4 μm.

### BRIEF DESCRIPTION OF THE DRAWINGS

FIG. 1 illustrates a cross-section view of a circuit protection device or apparatus that includes an electrical transient material, according to an exemplary embodiment.

FIG. 2 illustrates the electrical transient material in greater detail, according to an exemplary embodiment.

FIG. 3 illustrates an exemplary set of operations for manufacturing a circuit protection device or apparatus that comprises an electrical transient material, according to an embodiment of the disclosure.

### DETAILED DESCRIPTION

Circuit protection devices and apparatuses may employ electrical transient material (e.g., voltage variable material (VVM)). In some implementations, the electrical transient material includes a binder material. The binder material may include therein a mixture of conductive and semi conductive particles. Furthermore, the binder material may include therein a mixture of insulative particles or nonconductive particles. In another example, the electrical transient material includes a binder material that comprises conductive and semi conductive particles. At least some of the conductive and semi conductive particles may be coated with an insulative oxide film, nitride, silicon, or another one or more inorganic insulating coating.

At least one implementation of the electrical transient material includes conductive particles that have an irregular shape. In one implementation, the electrical transient material includes conductive particles that have an irregular shape and nonconductive particles that have a shape with a boundary that is generally rounded. For example, the nonconductive particles may be circular, oval, or the like. In one implementation, the conductive particles that have an irregular shape have at least one boundary surface or outer surface that is not rounded. For example, the conductive particles that have an irregular shape may have at least one boundary surface, outer surface, or side that is a straight line. In another example, the conductive particles that have an irregular shape may have at least a plurality of boundary surfaces, outer surfaces, or sides that are a straight line.

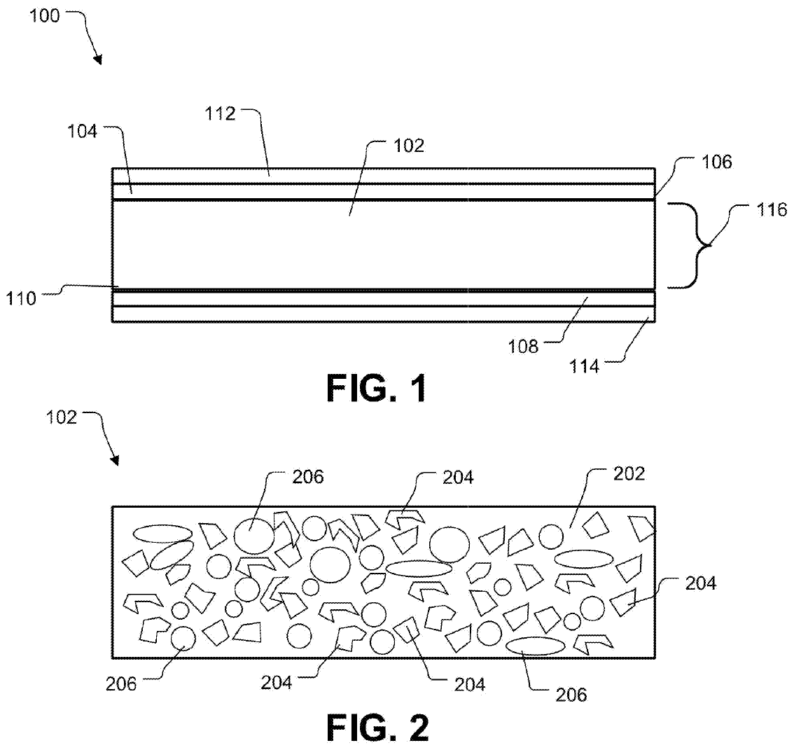

FIG. 1 illustrates a cross-section view of a circuit protection device or apparatus 100 that includes an electrical transient material 102 (e.g., VVM), according to an exemplary embodiment. In the illustrated embodiment, at least one electrically conductive layer 104 is applied over a first surface 106 of the electrical transient material 102. The electrically conductive layer 104 is shown as being in contact with the electrical transient material 102. However, one or more layers may be disposed between the electrical transient material 102 and the electrically conductive layer 104. In another embodiment, another electrically conductive layer 108 is applied over a second surface 110 of the electrical transient material 102.

In FIG. 1, the electrically conductive layer 108 is shown as being in contact with the electrical transient material 102. However, one or more layers may be disposed between the electrical transient material 102 and the electrically conductive layer 108. In some implementations, the electrically conductive layers 104 and 108 comprise copper (Cu). In some implementations, a layer 112 may be disposed over the layer 104. Moreover, in some implementations, a layer 114 may be disposed over the layer 108. In some implementations, the layers of 112 and 114 comprise tin (Tn). The layer 112 may mitigate against oxide forming on the electrically conductive layer 104. Similarly, the layer 114 may mitigate against oxide forming on the electrically conductive layer 108. In some implementations, the layers 112 and 114 are made from an insulative material. A width 116 of the electrical transient material 102 may be 1 mil or 25.4 μm. In one implementation, the width 116 of the electrical transient material 102 may be between 0.6-1 mil or 15.2-25.4 μm. In another implementation, the width 116 of the electrical transient material 102 may be between 0.6-6 mil or 15.2-152.4 μm. The disclosed widths for the width 116 are nonlimiting examples. In some examples, the width 116 may influence trigger voltages (V_{T}) and clamping voltages (V_{C}) associated with the electrical transient material 102.

FIG. 2 illustrates the electrical transient material 102 in greater detail, according to an exemplary embodiment. As is illustrated, the electrical transient material 102 includes a base material 202. The base material 202 may be a formulation including rubber, polyester, epoxy, polyimide and/or other polymer. The base material 202 may include a plurality of conductive particles 204 and a plurality of nonconductive particles 206. In one embodiment, the conductive particles 204 have an irregular shape. Specifically, in a particular embodiment, at least one or more the conductive particles 204 have a shape that includes at least one boundary surface, outer surface, or side that is a straight line. In at least one implementation, at least one or more the conductive particles 204 have an irregular shape that includes at least a plurality of boundary surfaces, outer or exterior surfaces, or sides that are flat or straight. In one implementation, the nonconductive particles 206 have a shape with a boundary or exterior surface that is generally rounded. In a particular implementation, one or more of the nonconductive particles 206 is a spherical particle and/or an oval shaped particle. In another implementation, one or more of the nonconductive particles 206 has an irregular shape. For example, one or more of the nonconductive particles 206 may have at least one or more boundary surface, outer or exterior surface, or side that is flat or straight.

The use of conductive particles 204 that have an irregular shape provides several advantages. Specifically, the conductive particles 204 having irregular shapes enhance conduction between the conductive particles 204, compared to conventional conductive particles that are spherical and/or ovalized. In particular, the flat or straight surface(s) of the conductive particles 204 enhance the tunneling effect through the base material 202. For example, in one implementation, the flat or straight surface(s) of the conductive particles 204 may allow the conductive particles 204 to be disposed in close proximity to one another within the base material 202. This close proximity arrangement of the conductive particles 204 may enhance the tunneling effect through the base material 202. The enhanced tunneling effect achieved by the conductive particles 204 having irregular shapes provides lower V_{T} and V_{C}, compared to V_{T} and V_{C} associated with conventional electrical transient materials. Electrical transient materials and VVM's trigger or change from a high impedance state to a low impedance state at the V_{T}, which is less than a maximum surge voltage. At some time duration (e.g, in ns) after the V_{T}, the electrical transient materials or VVM's reach a steady V_{C}. In one implementation, a steady V_{C} reached at 25 ns or around 25 ns. Eventually, the voltage due to an electrostatic discharge event will taper from the V_{C} to zero.

In various implementations, the electrical transient material 102 exhibits a V_{T} in the range of 125-130 V. Furthermore, in various implementations, the electrical transient material 102 exhibits a V_{C} in the range of 70-90 V. In one implementation, the electrical transient material 102 has a width of between 0.6-1 mil or 15.2-24.4 μm, and the electrical transient material has a voltage trigger voltage density of 8.2-4.9, defined as V_{T}/width in μm, and wherein the V_{T} is 125-130 V and the width is 15.2-24.4 μm. Correspondingly, the electrical transient material 102 has a clamping voltage density of 4.6-2.8, defined as V_{C}/width in μm, and wherein the V_{C} is 70-90 V and the width is 15.2-24.4 μm.

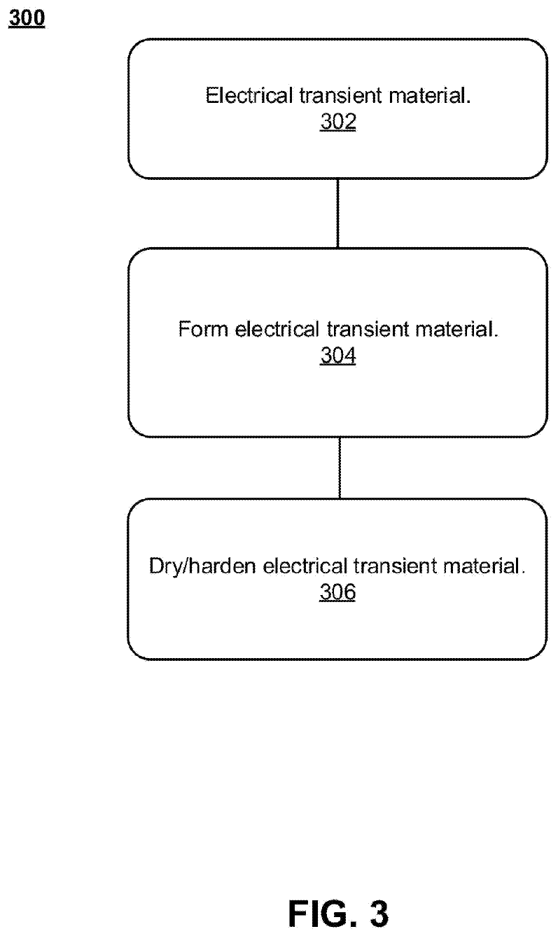

FIG. 3 illustrates an exemplary set of operations 300 for manufacturing a circuit protection device or apparatus 100 that comprises electrical transient material 102. At block 302, an electrical transient material may be provided in a powdered form. Alternatively, the electrical transient material may be provided in a liquid form, also known as an electrical transient material ink. The electrical transient material may include one or more conductive and nonconductive particles. Furthermore, in some implementations, the electrical transient material may comprise polymer and/or polyimide materials, including but not limited to epoxy resin. In various implementations, at least some of the conductive particles may have an irregular shape.

At block 304, the electrical transient material is formed to a desired shape and thickness. In one embodiment, the electrical transient material is applied to a rigid surface, such as a conductive substrate or a plate. For example, the electrical transient material in paste form may be applied to the rigid surface. In another example, the electrical transient material in ink form may be sprayed, printed, spin coated or casted onto the rigid surface. In one example, electrical transient material in ink form may be applied to the rigid surface using an application blade. In one implementation, the electrical may be structured by way of compression using a press or roll press to achieve a desired thickness of the electrical transient material. In another implementation, the electrical transient material in ink form may be structured using an application blade (e.g., Doctor Blade) to achieve a desired thickness of the electrical transient material. In one or more embodiments, the process of forming the electrical transient material may include providing one or more electrically conductive surface over a surface or surfaces of the electrical transient material.

At block 306, the formed electrical transient material is allowed to harden by drying, if necessary as part of the process of forming the electrical transient material. In one implementation, the formed electrical transient material is hardened in an oven.

While electrical transient material and a method for manufacturing electrical transient material have been described with reference to certain embodiments, it will be understood by those skilled in the art that various changes may be made and equivalents may be substituted without departing from the spirit and scope of the claims of the application. Other modifications may be made to adapt a particular situation or material to the teachings disclosed above without departing from the scope of the claims. Therefore, the claims should not be construed as being limited to any one of the particular embodiments disclosed, but to any embodiments that fall within the scope of the claims.

We claim:

1. An apparatus, comprising:
an electrical transient material; and
conductive particles disposed in the electrical transient material, at least one or more of the conductive particles have an irregular shape.

2. The apparatus according to claim 1, wherein the at least one or more of the conductive particles has an exterior surface that is flat or straight.

3. The apparatus according to claim 1, further comprising nonconductive particles disposed in the electrical transient material.

4. The apparatus according to claim 3, wherein at least one of the nonconductive particles is formed as a sphere or an oval shape.

5. The apparatus according to claim 1, wherein the electrical transient material comprises first and second opposite surfaces, and comprising an electrically conductive layer disposed over at least one of the first and second opposite surfaces.

6. The apparatus according to claim 1, wherein the electrical transient material is a voltage variable material (VVM).

7. A method, comprising:
providing an electrical transient material; and
disposing conductive particles in the electrical transient material, at least one or more of the conductive particles have an irregular shape.

8. The method according to claim 7, wherein the at least one or more of the conductive particles has an exterior surface that is flat or straight.

9. The method according to claim 7, further comprising disposing nonconductive particles in the electrical transient material.

10. The apparatus method to claim 9, wherein at least one of the nonconductive particles is formed as a sphere or an oval shape.

11. The apparatus method to claim 7, wherein the electrical transient material comprises first and second opposite surfaces, and forming an electrically conductive layer over at least one of the first and second opposite surfaces.

12. The apparatus method to claim 7, wherein the electrical transient material is a voltage variable material (VVM).

13. An apparatus, comprising:
an electrical transient material; and
conductive particles disposed in the electrical transient material, at least one or more of the conductive particles having an irregular shape,
wherein a width of the electrical transient material is between 0.6-1 mil or 15.2-24.4 μm, and the electrical transient material has a voltage trigger voltage density of 8.2-4.9, defined as voltage trigger/width in μm, and wherein the voltage trigger is 125-130 V and the width is 15.2-24.4 μm.

14. The apparatus according claim 13, wherein the electrical transient material has a clamping voltage density of 4.6-2.8, defined as clamping voltage/width in μm, and wherein the clamping voltage is 70-90 V and the width is 15.2-24.4 μm.

15. The apparatus according to claim 13, wherein the at least one or more of the conductive particles has an exterior surface that is flat or straight.

16. The apparatus according to claim 13, further comprising nonconductive particles disposed in the electrical transient material.

17. The apparatus according to claim 16, wherein at least one of the nonconductive particles is formed as a sphere or an oval, or at least one of the nonconductive particles has an irregular shape.

18. The apparatus according to claim 13, wherein the electrical transient material comprises first and second opposite surfaces, and comprising an electrically conductive layer disposed over at least one of the first and second opposite surfaces.

19. The apparatus according to claim 13, wherein the electrical transient material is a voltage variable material (VVM).
